(19) United States
(12) Patent Application Publication
(10) Pub. No.: US 2018/0246146 A1
(43) Pub. Date: Aug. 30, 2018

(54) SENSOR DEVICE FOR CONNECTION TO A MEASUREMENT CONNECTION OF A CAPACITIVELY CONTROLLED FEEDTHROUGH

(71) Applicant: General Electric Technology GmbH, BADEN (CH)

(72) Inventors: Sebastian Rohde, Koeln (DE); Sebastian Coenen, Willich (DE); Bartlomiej Dolata, Krefeld (DE)

(73) Assignee: General Electric Technology GmbH, BADEN (CH)

(21) Appl. No.: 15/553,446

(22) PCT Filed: Feb. 24, 2016
(86) PCT No.: PCT/EP2016/053836

§ 371 Date: Aug. 24, 2017

(30) Foreign Application Priority Data
Feb. 24, 2015 (DE) 10 2015 203 300.7

(51) Int. Cl. G01R 15/16; G01R 15/06

(52) U.S. Cl. CPC G01R 15/16; G01R 15/06

(57) ABSTRACT

The invention relates to a sensor device comprising an adapter for connection to a measurement connection of a capacitively controlled bushing. The adapter can be connected to the measuring connection and a fastening device. A sensor housing can be rigidly connected to the fastening device by means of the adapter. The adapter has an overvoltage arrestor that can be connected between the measurement connection (64) and the fastening device. The adapter is designed such that a main capacity of the bushing can be measured at the adapter before the sensor housing is arranged on the adapter.

The invention relates to a sensor device for connection to a measurement connection of a capacitively controlled bushing according to the preamble of claim 1 and to a method according to the preamble of the independent claim.

It is known that bushings, in particular of high-voltage transformers, are continuously monitored.

A measurement system for continuously monitoring a high-voltage bushing is thus known from EP 2 760 095 A1, for example. A measurement circuit is connected to the measurement connection via a connection cable.

Measurement systems of this kind often have a specific frequency response which must first be recorded when measuring transient processes in order to subsequently take said frequency response into account during operation for signal processing.

Furthermore, it is known that transient overvoltages in the bushing itself or in the system assigned to the bushing, for example a transformer, may cause damage. An example of a transient overvoltage of this kind is a single-pole ground fault or a lightening stroke.

The problem addressed by the invention is therefore that of better detecting transient overvoltages and of ensuring operation of the bushing.

The problem on which the invention is based is solved by a sensor device according to claim 1 and by a method according to an independent claim. Advantageous developments are described in the dependent claims. Features which are essential to the invention can also be found in the following description and in the drawings, it being possible for the features to be essential to the invention both when considered alone and in different combinations, without being explicitly referred to again.

An adapter can advantageously be connected to a measurement connection and a fastening device. A sensor housing can be connected to the fastening device by means of the adapter. In particular if a sensor device is improperly installed, high-voltage potential can be applied to the measurement connection as a result of non-contacting of the measurement connection, which can lead to the bushing being destroyed. By means of the adapter, a test can advantageously be brought right up to the adapter, without the components arranged in the sensor housing influencing this result. In particular, a main capacity of the bushing can be measured by means of the adapter. By checking the main capacity, it is also ensured that the adapter has been contacted correctly both at the measurement connection and at the fastening device.

In an advantageous embodiment, the adapter comprises an overvoltage arrester that can be connected between the measurement connection and the fastening device. The potential of the measurement connection is maintained at a specified potential by means of a sparkover of the overvoltage arrester. An adapter is thus provided that ensures the safe operation of the bushing.

In an advantageous embodiment, the sensor device works according to the principle of the capacitive voltage divider, in which a measurement capacitor can be arranged between the measurement connection of the capacitively controlled bushing and ground. Since the measurement capacitor has a number of surface-mounted capacitor components connected in parallel, the parasitic inductance inherent to every capacitor component can advantageously be significantly reduced by means of both the increased number and the surface mounting. From a specific frequency, the inductively active components of a capacitor prevail. This starts from the particular resonance frequency. For capacitors having low capacitances, said resonance frequency is higher, as a result of which an increased number of capacitor components are provided in the present case. Owing to the surface mounting of the capacitor components, a measurement bandwidth gain is additionally achieved, which is advantageous over wired components. An advantageous frequency response of the sensor device can thus be achieved over wide frequency ranges for the purpose of a substantially constant attenuation. In this way, the frequency and amplitude of the transients, in the form of lightning strokes, switching operations or ground faults, can be detected and recorded without additional signal processing complexity with respect to the frequency response of the sensor device.

In an advantageous embodiment, the capacitor components are substantially equidistant from a longitudinal axis of an inner conductor of the sensor device. Owing to the equidistance, the particular capacitor component is substantially supplied with an identical phase position by the applied signal starting from the measurement connection side. As a result, there are improvements in terms of the measuring signal to be decoupled.

In an advantageous embodiment, the sensor device has a substantially coaxial design with respect to the longitudinal axis. The substantially coaxial design reduces the influence of the shape of the sensor device on the measuring signal to be decoupled, since the electric field is formed radially and thus uniformly around the inner conductor.

In an advantageous embodiment, the number of capacitor components are arranged on one printed circuit board and the printed circuit board is arranged substantially in one vertical plane of the longitudinal axis. The equidistance of the capacitor components is thereby advantageously made possible and the coaxial design achieved.

In an advantageous embodiment, the capacitor components are arranged on either side of the printed circuit board. This advantageously allows the number of capacitor components to be increased, leading to a further reduction of leakage inductance.

In another advantageous embodiment, a further number of surface-mounted capacitor components connected in parallel are arranged on an additional printed circuit board, the additional printed circuit board being arranged in an additional vertical plane of the longitudinal axis. This measure also advantageously results in the number of capacitor components being increased and thus the leakage inductance being reduced and the total capacitance being increased, which is advantageous for the frequency response and the output voltage of the sensor device.

In an advantageous embodiment, the capacitor components are each connected between a first planar inner conductor and a second planar outer conductor. The planar design of the conductor reduces the inductance per unit length, which is advantageous for the frequency response. Moreover, it is thus easier to produce the printed circuit board.

In an advantageous embodiment, the distance between the measurement capacitor and the measurement connection can be reduced by the substantially rigid connectivity between the sensor device and the bushing. This reduction in distance between the measurement capacitor and the measurement connection results in the line inductance being significantly reduced and thus extends the frequency range available for the measurement.

In an advantageous embodiment, a measurement adapter is designed to be attached to the measurement connection. A housing adapter is designed to be arranged in a rigid and fluid-tight manner on a flange of the bushing and is designed to receive the measurement connection adapter in an electrically contactless manner. The sensor housing can be connected to the housing adapter in a rigid and fluid-tight manner. In addition to an adaptation to different embodiments of the measurement connection and the flange of the bushing, the distance between the measurement connection and the measurement capacitor is significantly reduced owing to the housing adapter, the measurement connection adapter and the sensor housing. In addition, a stable and secure connection to the bushing is thus produced, which connection also withstands external influences such as weather.

In an advantageous embodiment, the measurement connection adapter can be connected to the inner conductor portion that protrudes from the printed circuit board on the side facing away from the measurement connection. A simple and short connection between the measurement connection and the measurement capacitor is thus produced.

In an advantageous embodiment, the capacitor components are each formed as plastics film capacitors which are advantageously characterized by their self-healing property. Although there is a small loss of capacitance if the corresponding dielectric breaks down, said capacitors are characterized by an increased service life.

Additional features, possible uses and advantages of the invention can be found in the following description of embodiments of the invention that are shown in the drawings. All of the features described or represented alone or in any combination form the subject matter of the invention, irrespective of how said features are set out in the claims or the dependency references thereof and irrespective of the wording or representation thereof in the description or in the drawings, respectively. The same reference signs are used for functionally equivalent sizes and features in all the drawings, even for different embodiments.

Exemplary embodiments of the invention are described with reference to the title in the following. In the drawings:

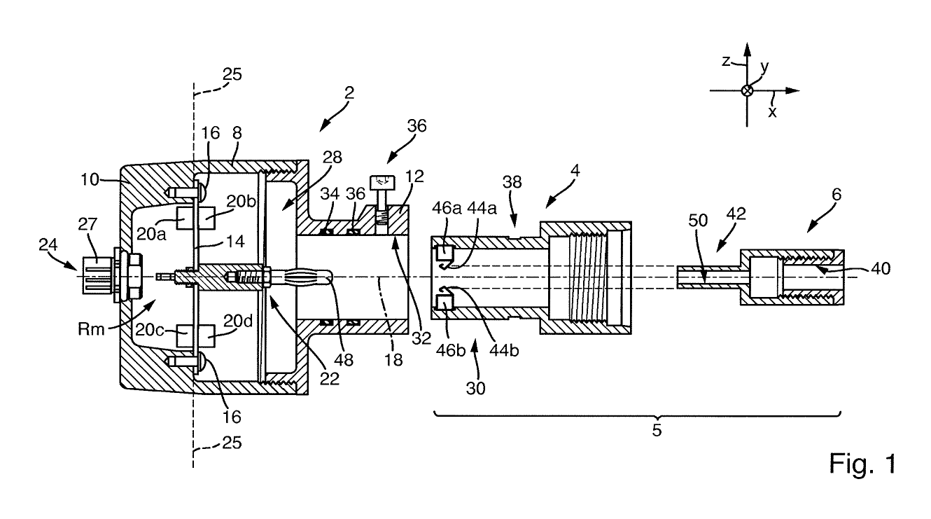

FIG. 1 is a schematic sectional view of a sensor device;

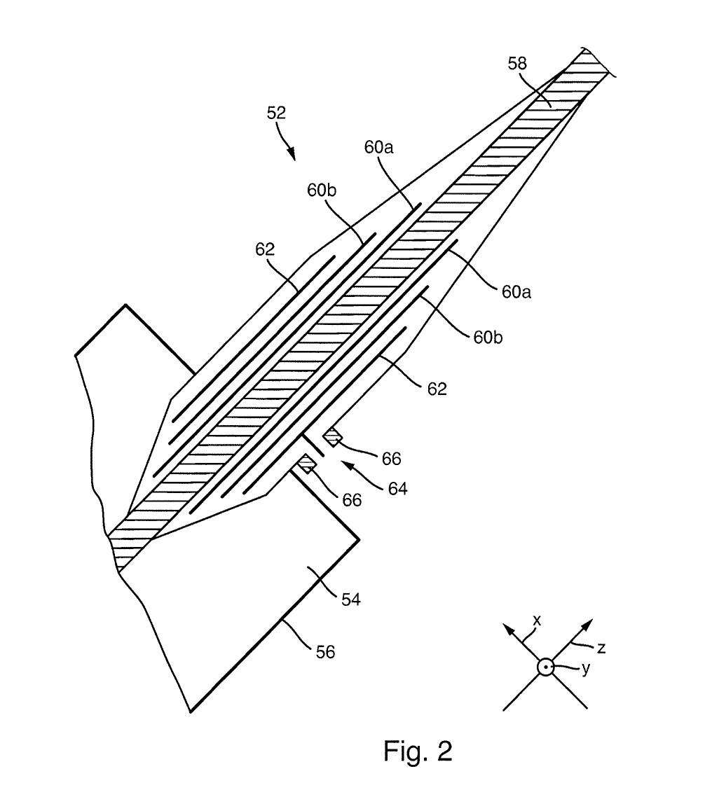

FIG. 2 is a schematic view of a bushing;

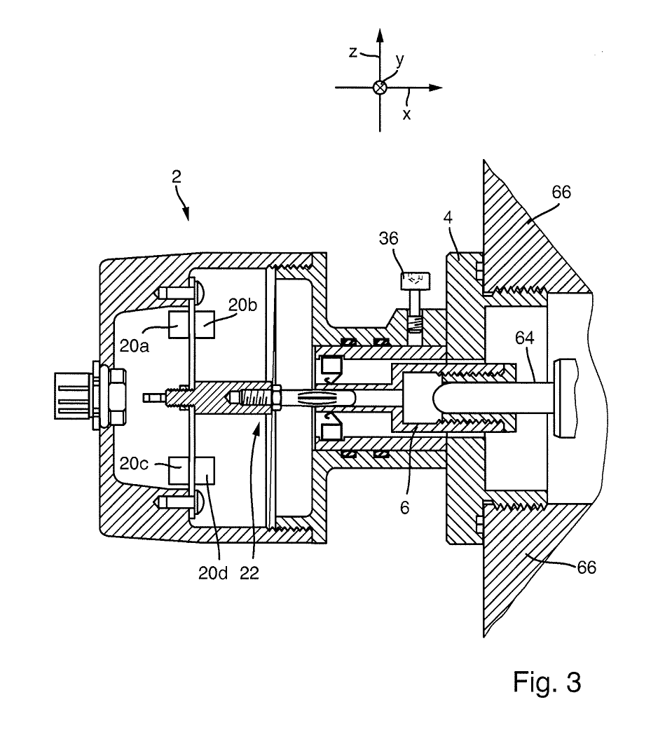

FIG. 3 is a schematic sectional view of a sensor device when installed;

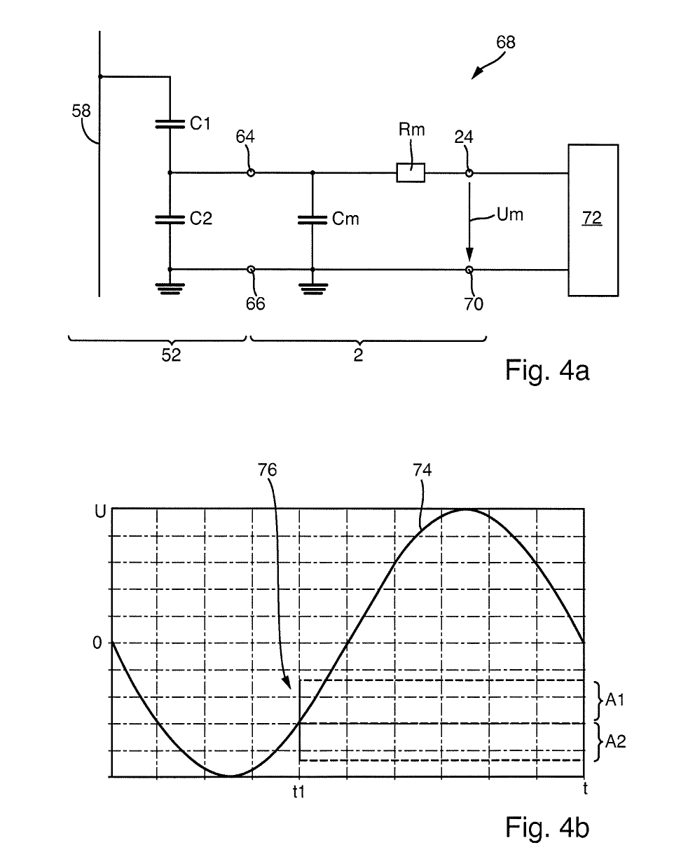

FIG. 4a is a schematic equivalent circuit diagram;

FIG. 4b is a schematic voltage-time diagram;

FIG. 4c is a schematic attenuation-frequency diagram;

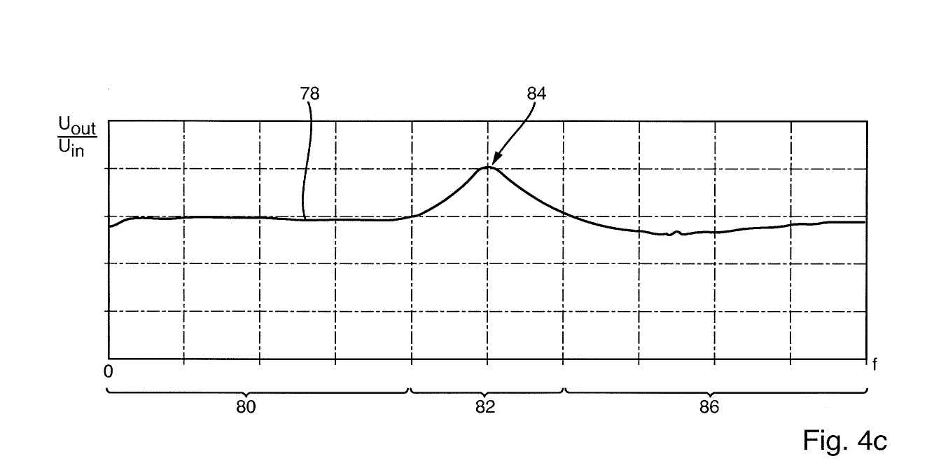

FIG. 5 is a schematic plan view of a printed circuit board;

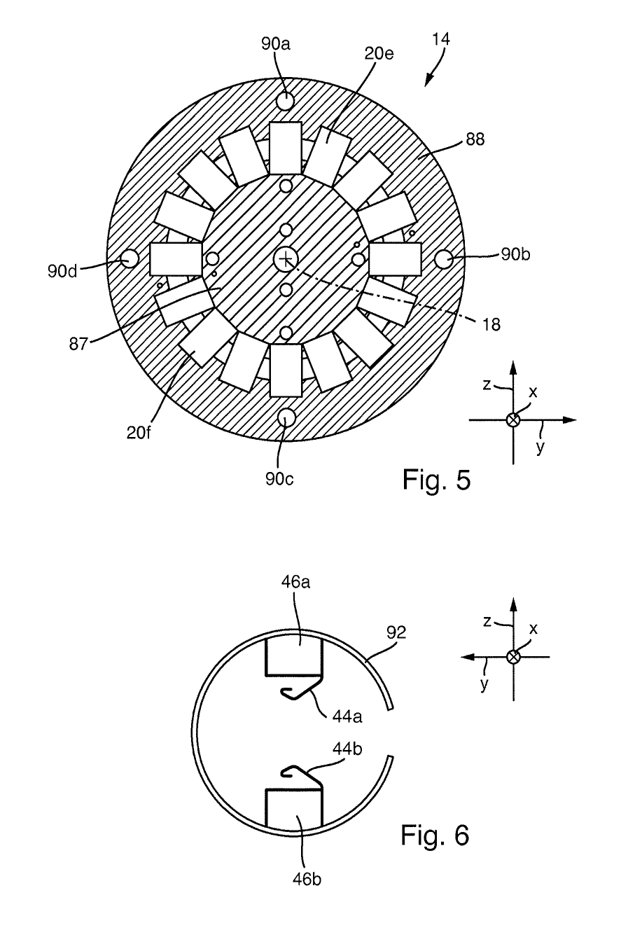

FIG. 6 is a schematic plan view of a spring ring; and

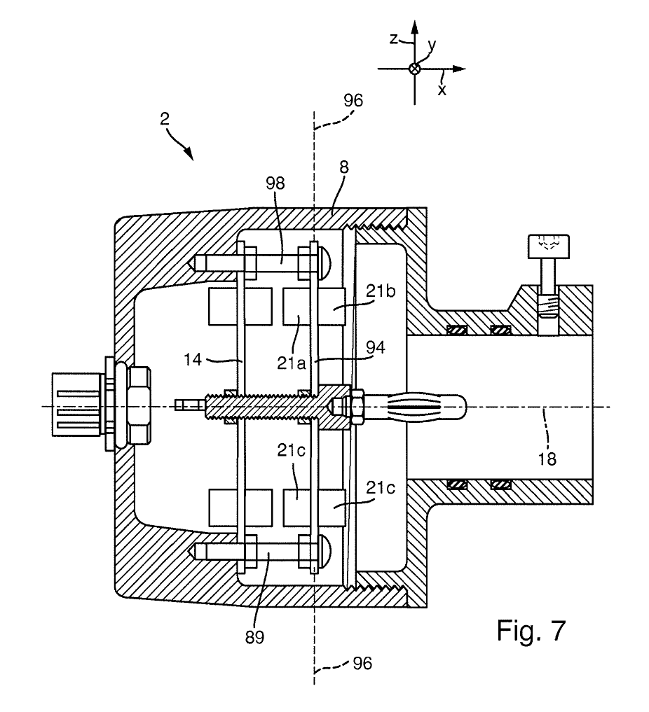

FIG. 7 is a schematic sectional view of an additional sensor device.

FIG. 1 is a schematic sectional view of a sensor device 2. A housing adapter 4 and a measurement connection adapter 6 are assigned to the sensor device 2, the housing adapter 4 and the measurement connection adapter 6 together being referred to as the adapter 5. The housing adapter 4 and the measurement connection adapter 6 can also be rigidly interconnected. The sensor housing 8 comprises a first housing portion 10 and a second housing portion 12, the first housing portion 10 having an internal thread in the x direction, in which an external thread of the second housing portion 12 engages to form a fluid-tight and rigid closure.

A printed circuit board 14 is mechanically and electrically conductively connected to the sensor housing 8 inside the sensor housing 8 by means of connection elements 16. The sensor housing 8 has a longitudinal axis 18, from which the capacitor components 20 are equidistant. A first inner conductor portion 22 protrudes from the printed circuit board 14 along the longitudinal axis 18 in the x direction. The measurement connection adapter 6 is also referred to as the second inner conductor portion. The printed circuit board 14 comprises capacitor components 20 on either side. The capacitor components 20 are each arranged annularly around the longitudinal axis 18. The printed circuit board 14 itself lies in a vertical plane 24 of the longitudinal axis 18.

The sensor housing 8, the housing adapter 4 and the measurement connection adapter 6 are made of electrically conductive material. The sensor housing 8 can be grounded to a grounded or groundable measurement connection at a bushing via the sensor adapter 4. All of the capacitor components 20 are thus each connected between the inner conductor 22, which is connected to a measurement connection of the bushing, and the groundable sensor housing 8.

The sensor device 2, the housing adapter 4 and the measurement connection adapter 6 are all substantially coaxial with respect to the longitudinal axis 18, i.e. are substantially rotationally symmetrical about the longitudinal axis 18. A resistor Rm protrudes from the printed circuit board 14 counter to the x direction, which resistor is electrically conductively connected to an externally accessible measurement connection 24 via an edge connector 27 counter to the x direction in a manner that is not shown.

A current transformer in the form of a coil is arranged around the first inner conductor portion 22 coaxially with the longitudinal axis 18 in a manner that is not shown in an inner space 28 of the sensor housing 8 between the second housing portion 12 and the printed circuit board 14.

The housing adapter 4, together with a sensor-housing-side portion 30, can be received in a cylindrical receiving space 32 of the sensor housing 8. Seals 34 and 36 are annular and intended to fluidically connect the portion 30 and the sensor housing 8. A clamping screw 36, which can be fed radially to the portion 30 in the sensor housing 8, is designed to engage in an annular groove 38. Instead of the clamping screw 36 and the groove 38, the portion 30 can also be fixed in the receiving space 32 in another manner. The sensor housing 8 can thus be connected to the housing adapter 4 in a rigid and fluid-tight manner.

The measurement connection adapter 6 comprises, in the x direction, an inner receiving portion 40, which can be connected to the measurement connection. The measurement connection is designed in particular as a pin that can be received in the receiving portion 40. Counter to the x direction, the measurement connection 6 comprises a portion 42 that is formed radially outwards so as to electrically contact respective springs 44 of overvoltage arrester components 46. The overvoltage arrester components 46 are thus connected to the measurement connection adapter 6, which is attached to the measurement connection, and to the grounded housing adapter 4 between ground and a ground coating of the bushing.

The correct installation of the measurement connection adapter 6 and the housing adapter 4 can thus be checked in a checking step without the arranged sensor housing 8 between the portion 42 and the outside of the housing adapter 4 by measuring the main capacity of the bushing. The main capacity of the bushing 52 can be measured, for example, by applying a voltage to the high-voltage side of the bushing 52 at a first point in time and measuring the time from the first point in time to a second point in time until the voltage between the portion 42 and the housing adapter 42 increases to a predetermined value. After a positive check, i.e. the measured value matches a desired setpoint, the sensor housing 8 can be connected in a fluid-tight and rigid manner to the housing adapter 4 by means of the portion 30. A positive check can therefore take place if the measured value matches a further measured value previously determined directly at the measurement connection. The measurement connection adapter 6 forms part of the inner conductor of the sensor device 2. The adapter 5, which comprises the housing adapter 4 and the measurement connection adapter 6, can thus be connected to the measurement connection 64 and the fastening device 66. The main capacity of the bushing 52 can be measured at the adapter 5 in accordance with the checking step. Following the successful checking step, the sensor housing 8 can be connected to the fastening device 66 by means of the adapter 5.

After the sensor housing 8 has been arranged on the adapter 5, a measurement can be taken. If the overvoltage arrester 46 has been triggered, the sensor device 2 would not be able to detect a signal.

The first inner conductor portion 22 comprises a bunch plug 48, which can be received in a receiving portion 50 of the measurement connection adapter 6. The measurement connection adapter 6 can thus be connected to an inner conductor portion 22 or 48 protruding from the printed circuit board 14 on the side facing away from the measurement connection.

FIG. 2 is a schematic view of an example of a design of a bushing 52. The bushing 52 connects an outer chamber to an inner chamber 54, filled with insulating fluid, of a high-voltage transformer 56 and is also referred to as a high-voltage bushing. The bushing 52 comprises the high-voltage conductor 58 and control coatings 60 which are arranged coaxially with the high-voltage conductor 58, are differently stepped in the z direction and are insulated from one another. A ground coating 62 is designed as the outermost coating and is guided out of the bushing 52 via the measurement connection 64, which is designed as a pin. A grounded flange 66 is arranged around the pin according to the measurement connection 64, which flange is generally referred to as the fastening device. The measurement connection 64 can be accessed from the outside of the bushing 52. The measurement connection 64 is insulated against the flange 66 or another fastening device and applied to one of the outer conductive layers, by way of example in the present case to the ground coating 62, of the capacitively controlled bushing 52, in order to allow the dissipation factor, the capacitance and the partial discharge to be measured, while the flange 66 of the bushing 52 is grounded.

The measurement connection adapter 6 is thus first attached to the measurement connection 64 in the x direction, then the housing adapter 4 is arranged on the flange 66 in a manner in which it does not conductively receive the measurement connection adapter 6 and finally the sensor housing 8 is arranged on the housing adapter 4.

In FIG. 3, the sensor device 2 is connected in a fluid-tight and rigid manner to the bushing 52 by means of the flange 66. Only the clamping screw 36 is not yet shown to be clamped. FIG. 3 thus illustrates how the measurement connection 64 is received by the receiving portion 40 of the measurement connection adapter 6 and thus produces an electrical connection between the measurement connection 64 and the capacitor components 20 by means of the inner conductor portion 22. In contrast to FIG. 1, FIG. 3 shows another embodiment of the housing adapter 4. The housing adapter 4 engages in an inner thread of the flange 66 in the x direction. The flange 66 thus provides a measurement opening through which the measurement connection 64 is guided. The measurement connection 64 is electrically conductively connected to the control coating, which can be grounded to a grounding cap, i.e. to the ground coating 62.

FIG. 4a is a schematic equivalent circuit diagram 68 of the measurement principle used in the present case that is based on a capacitive divider. The bushing 52 comprises the high-voltage conductor 58. A main capacity C1 is the capacitor between the high-voltage conductor 58 and the measurement connection 64. A tap capacitor C2 is a capacitor between the measurement connection 64 and the grounded fastening flange 66. The measurement connection 64 and the flange 66, which is grounded, are used as an interface between the bushing 52 and the sensor device 2. A measurement capacitor Cm is formed by the capacitor components 20. The resistor Rm is arranged between the measurement capacitor Cm and the measurement connection 24. A measuring voltage Um can be detected between the measuring connection 24 and a grounded connection 70 by an evaluation unit 72. The resistor Rm terminates the line between the connections 24 and 70 and the evaluation unit 72 with a corresponding characteristic impedance.

FIG. 4b is a schematic voltage-time diagram that shows voltage U over time t. A voltage characteristic 74 of a phase having a frequency of 50 Hz is shown. The voltage characteristic 74 has a deviation in the form of a transient characteristic 76 approximately at a point in time t1, which has amplitudes A1 and A2. A transient characteristic 76 of this kind can be shown in the measuring voltage Um by the sensor device 2.

FIG. 4c is an example of a schematic attenuation-frequency diagram, a voltage Uin that has a known voltage waveform, in particular a known frequency between the high-voltage conductor 58 and ground, having been specified, and a voltage Uout between the measurement connection 24 and ground having been measured. The attenuation characteristic 78 has an almost constant attenuation in a first lower frequency range 80, the attenuation decreases in a middle frequency range 82 in the region of the resonance frequency 84 and, in a high frequency range 86, an almost constant attenuation is again achieved.

FIG. 5 is a plan view of the printed circuit board 14. The capacitor components 20 are arranged annularly around the longitudinal axis 18. The capacitor components 20 are electrically conductively connected to a first planar conductor 87 towards the longitudinal axis 18 and to a second planar conductor 88 on the outside. In addition, two additional overvoltage arrester components are arranged between the first conductor 87 and the second conductor 88, in a manner that is not shown. The first conductor 87 is substantially annular and only punctuated by fastening or bushing holes. The second conductor 88 is substantially annular. The conductors 87 and 88 are substantially coaxial with the longitudinal axis 18. Contacting holes 90 are used to mechanically and electrically contact the sensor housing 8.

FIG. 6 is a schematic plan view of an annular spring 92, on which the overvoltage arrester components 46 are arranged. The spring 92 can be received in a corresponding inner groove in the portion 30 of the housing adapter 4.

FIG. 7 is another embodiment of the sensor device 2 without the housing adapter 4 and the measurement connection adapter 6. In contrast to FIG. 1, an additional printed circuit board 94 is arranged in the sensor housing 8, which printed circuit board is spaced from the vertical plane 24 in an additional vertical plane 96 of the longitudinal axis 18. The printed circuit board 94 is constructed similarly to the printed circuit board 14. Corresponding connection means 98 produce an electrical and mechanical connection to the sensor housing 8.

The surface-mounted capacitor components can also be referred to as SMD capacitor components, where SMD stands for surface mounted device.

What is claimed is:

1. A sensor device comprising an adapter and for connection to a measurement connection and a grounded fastening device of a capacitively controlled bushing, it being possible for a sensor housing being to be rigidly connected to the fastening device by means of the adapter, characterized in that the adapter can be connected to the measuring connection and the fastening device, in that the adapter has an overvoltage arrester that can be connected between the measurement connection and the fastening device, and in that the adapter is designed such that a main capacity of the bushing can be measured at the adapter before the sensor housing is arranged on the adapter.

2. (canceled)

3. (canceled)

4. The sensor device according to claim 1, wherein the adapter comprises a measurement connection adapter and a housing adapter, wherein the measurement connection adapter is designed to be attached to the measurement connection wherein the housing adapter is designed to be arranged in a rigid and fluid-tight manner on a fastening device of the bushing and is designed to receive the measurement connection adapter, and wherein the sensor housing can be connected in a rigid and fluid-tight manner to the housing adapter.

5. The sensor device according to claim 1, wherein the sensor device comprises a measurement capacitor that can be arranged between the measurement connection and ground, and wherein the measurement capacitor comprises a number of surface-mounted capacitor components connected in parallel.

6. The sensor device according to claim 5, wherein the capacitor components are equidistant from a longitudinal axis of an inner conductor of the sensor device.

7. The sensor device according to claim 1, wherein the sensor device has a coaxial design with respect to the longitudinal axis of the inner conductor of the sensor device.

8. The sensor device according to claim 5, wherein the number of capacitor components are arranged on a printed circuit board, and wherein the printed circuit board is arranged in a vertical plane of the longitudinal axis of the inner conductor of the sensor device.

9. The sensor device according to claim 8, wherein the capacitor components are arranged on either side of the printed circuit board.

10. The sensor device according to claim 8, wherein a further number of surface-mounted capacitor components connected in parallel are arranged on an additional printed circuit board, and wherein the additional printed circuit board is arranged in an additional vertical plane of the longitudinal axis of the inner conductor of the sensor device.

11. The sensor device according to claim 5, wherein the capacitor components are each connected between a first planar inner conductor and a second planar outer conductor.

12. The sensor device according to claim 8, wherein the measurement connection adapter can be connected to the inner conductor portion that protrudes from the printed circuit board on the side facing away from the measurement connection.

13. A method for connecting a sensor device to a measurement connection and a grounded fastening device of a capacitively controlled bushing, comprising the steps of rigidly connecting a sensor housing to the fastening device by means of an adapter, connecting an adapter to the measurement connection and the fastening device, wherein the adapter has an overvoltage arrester and comprising the step of connecting it between the measurement connection and the fastening device, and providing the adapter such that a main capacity of the bushing can be measured at the adapter before the sensor housing is arranged on the adapter.

14. (canceled)

15. (canceled)
